(19) United States
(12) Patent Application Publication
(10) Pub. No.: US 2024/0333221 A1
(43) Pub. Date: Oct. 3, 2024

(54) TRACKER CIRCUIT, COMMUNICATION DEVICE, AND VOLTAGE SUPPLY METHOD

(71) Applicant: Murata Manufacturing Co., Ltd., Nagaokakyo-shi (JP)

(72) Inventors: Muneharu KATO, Nagaokakyo-shi (JP); Sho OKAMOTO, Nagaokakyo-shi (JP); Kouji YAMAGUCHI, Nagaokakyo-shi (JP)

(21) Appl. No.: 18/610,946

(22) Filed: Mar. 20, 2024

(30) Foreign Application Priority Data
Mar. 27, 2023 (JP) 2023-050606

(51) Int. Cl. H03F 1/02; H03F 3/24

(52) U.S. Cl. CPC H03F 1/0233; H03F 3/245; H03F 2200/105; H03F 2200/451

(57) ABSTRACT

A tracker circuit includes an A-ET circuit, a voltage generating circuit and an output switching circuit. The A-ET circuit generates a continuously varying voltage that is associated with an envelope of a signal to be amplified by a power amplifier. The voltage generating circuit generates a peak voltage that is higher than a maximum voltage value of the continuously varying voltage. The output switching circuit outputs the continuously varying voltage to the power amplifier as a first supply voltage of the power amplifier when an envelope value of the signal to be amplified by the power amplifier is smaller than a threshold; and outputs the peak voltage to the power amplifier as the first supply voltage of the power amplifier when the envelope value is greater than the threshold.

### CROSS REFERENCE TO RELATED APPLICATION

This application claims priority to Japanese Patent Application No. 2023-050606, filed Mar. 27, 2023, the entire content of which is hereby incorporated by reference in its entirety.

### TECHNICAL FIELD

The present disclosure relates to tracker circuits, communication devices, and voltage supply methods.

### BACKGROUND

In recent years, envelope tracking (ET) has been applied to power amplifier circuits to enhance power-added efficiency. An example circuit, as described in U.S. Patent Publication No. 2018/0159476, includes a DC-DC converter and an error amplifier for generating a supply voltage to be supplied to a power amplifier.

With this configuration, however, when the range of supply voltage variation to the power amplifier widens, the tracker efficiency may degrade.

### SUMMARY OF THE INVENTION

Thus, according to exemplary aspects of the present disclosure, tracker circuits, communication devices, and voltage supply methods are provided that suppress degradation of tracker efficiency.

A tracker circuit according to an exemplary aspect includes an analog envelope tracking (A-ET) circuit configured to generate a continuously varying voltage that is associated with an envelope of a signal to be amplified by a power amplifier, a voltage generating circuit configured to generate a peak voltage that is higher than a maximum voltage value of the continuously varying voltage, and an output switching circuit configured to receive the continuously varying voltage and the peak voltage. The output switching circuit is configured to, when an envelope value of the signal to be amplified by the power amplifier is smaller than a threshold, output the continuously varying voltage to the power amplifier as a first supply voltage of the power amplifier, and when the envelope value is greater than the threshold, output the peak voltage to the power amplifier as the first supply voltage of the power amplifier.

A tracker circuit according to another exemplary aspect includes an A-ET circuit configured to generate a continuously varying voltage, a voltage generating circuit configured to generate a peak voltage that is higher than a maximum voltage value of the continuously varying voltage, and an output switching circuit configured to receive the continuously varying voltage and the peak voltage. The output switching circuit is configured to, when the average power within a single frame is smaller than a threshold, output the continuously varying voltage to a power amplifier, and when the average power within a single frame is greater than the threshold, output the peak voltage to the power amplifier.

A communication device according to another exemplary aspect includes the tracker circuit according to some aspects, a signal processing circuit configured to process a radio-frequency signal, and a radio-frequency circuit that includes the power amplifier and that is configured to transfer the radio-frequency signal between the signal processing circuit and an antenna.

A voltage supply method according to an exemplary aspect includes generating a continuously varying voltage; generating a peak voltage that is higher than a maximum voltage value of the continuously varying voltage; and when an envelope value is smaller than a threshold, outputting the continuously varying voltage to a power amplifier, and when an envelope value is greater than the threshold, outputting the peak voltage to the power amplifier.

Moreover, a voltage supply method is provided according to another exemplary aspect that includes generating a continuously varying voltage; generating a peak voltage that is higher than a maximum voltage value of the continuously varying voltage; and when the average power within a single frame is smaller than a threshold, outputting the continuously varying voltage to a power amplifier, and when the average power within a single frame is greater than the threshold, outputting the peak voltage to the power amplifier.

The tracker circuits, communication device, and voltage supply methods according to some aspects of the present disclosure suppress degradation of tracker efficiency.

### BRIEF DESCRIPTION OF THE DRAWINGS

FIG. 1A is a graph illustrating an example of supply voltage variations in an average power tracking (APT) mode;

FIG. 1B is a graph illustrating an example of supply voltage variations in an analog envelope tracking (A-ET) mode;

FIG. 1C is a graph illustrating an example of supply voltage variations in a digital envelope tracking (D-ET) mode;

FIG. 2 is a circuit configuration diagram of a communication device according to a first exemplary embodiment;

FIG. 3 is a circuit configuration diagram of a tracker circuit according to the first exemplary embodiment;

FIG. 4 is a flowchart illustrating a voltage supply method according to the first exemplary embodiment;

FIG. 5A is a graph that plots the voltage supplied to a power amplifier by a tracker circuit according to a comparative example;

FIG. 5B is a graph that plots the voltage supplied to a power amplifier by the tracker circuit according to the first exemplary embodiment;

FIG. 6 is a flowchart illustrating a voltage supply method according to a modification of the first exemplary embodiment;

FIG. 7 is a plan view of an exemplary layout of circuit elements of the tracker circuit according to the first exemplary embodiment;

FIG. 8 is a circuit configuration diagram of a tracker circuit according to a second exemplary embodiment; and

FIG. 9 is a plan view of an exemplary layout of circuit elements of the tracker circuit according to the second exemplary embodiment.

### DETAILED DESCRIPTION OF EMBODIMENTS

Hereinafter, exemplary embodiments of the present disclosure will be described in detail with reference to the drawings. The embodiments described below represent comprehensive or specific examples. Details such as numerical values, shapes, materials, constituent elements, and arrangements and connection modes of the constituent elements provided in the following embodiments are illustrative and are not intended to limit the present disclosure.

The drawings are schematically illustrated with some emphasis, omissions, or proportion adjustments to depict the present disclosure and do not necessarily represent exact details; thus, the shapes, positional relationships, and proportions can differ from actual implementations. Identical reference numerals are assigned to substantially the same configuration elements across the drawings, and redundant descriptions of these configuration elements can be omitted or simplified.

In the circuit configurations of the present disclosure and according to the exemplary aspects, the term “couple” applies when one circuit element is directly coupled to another circuit element via a connection terminal and/or an interconnect conductor, and the term also applies when one circuit element can be electrically coupled to another circuit element via still another circuit element. The term “directly couple” applies when one circuit element is directly coupled to another circuit element via a connection terminal and/or an interconnect conductor without involving still another circuit element. The expression “C is coupled between A and B” refers to a situation in which one end of C is coupled to A, and the other end of C is coupled to B and a situation in which C is provided in series in the path connecting A and B. The term “path connecting A and B” refers to a path formed by a conductor that electrically couples A to B.

In the following description, the term “terminal” refers to a point at which a conductor within an element terminates. When the impedance of a conductor between elements is sufficiently low, the “terminal” is interpreted not only as a single point but also as any point in the conductor between the elements, or as the entire conductor.

It is also noted that terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

In this specification, unless otherwise noted, ordinal numerals such as “first” and “second” do not indicate the number or order of constituent elements; the ordinal numerals are used for the purpose of avoiding confusion of constituent elements of the same type and distinguishing between the constituent elements.

### Tracking Modes

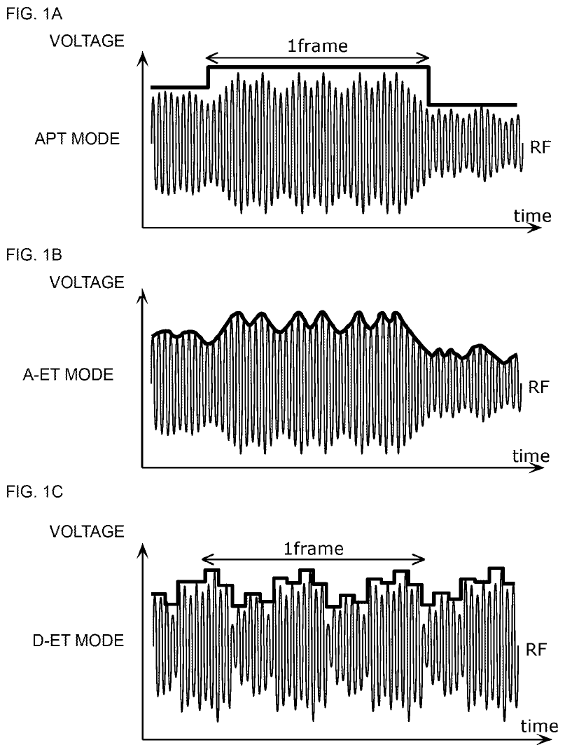

First, as a technique for high efficiency amplification of radio-frequency signals, tracking modes for supplying to power amplifiers a supply voltage that is dynamically adjusted over time based on radio-frequency signals will be described. Tracking modes dynamically adjust supply voltage applied to power amplifiers. Among various types of tracking modes, an average power tracking (APT) mode, an analog envelope tracking (A-ET) mode, and a digital envelope tracking (D-ET) mode will be described with reference to FIGS. 1A to 1C. In FIGS. 1A to 1C, the horizontal axis represents time, and the vertical axis represents voltage. The thick solid line represents the supply voltage, and the thin solid line (waveform) represents the modulated wave.

FIG. 1A is a graph illustrating an example of supply voltage variations in the APT mode. In the APT mode, the supply voltage varies across multiple discrete voltage levels in single-frame units, based on the average power.

For purposes of this disclosure, the term “frame” refers to a unit that constitutes a radio-frequency signal (e.g., a modulated wave). For example, in 5th Generation New Radio (5GNR) and Long Term Evolution (LTE), a frame comprises ten subframes. Each subframe includes multiple slots, and each slot includes multiple symbols. The subframe length is 1 ms, and the frame length is 10 ms.

The mode in which the voltage level varies in single-frame units or larger units based on the average power is called the APT mode. This mode is distinct from the mode in which the voltage level varies in units smaller than single-frame units (for example, subframes, slots, or symbols).

FIG. 1B is a graph illustrating an example of supply voltage variations in the A-ET mode. In the A-ET mode, the envelope of a modulated wave is tracked by continuously varying the supply voltage in response to an envelope signal.

An envelope signal represents the envelope of a modulated wave. The envelope value is expressed, for example, as the square root of (I²+Q²). (I, Q) represents a constellation point. A constellation point represents a digitally modulated signal on a constellation diagram. (I, Q) is identified, for example, by a baseband integrated circuit (BBIC) based on transmit information.

FIG. 1C is a graph illustrating an example of supply voltage variations in the D-ET mode. In the D-ET mode, the envelope of a modulated wave is tracked by varying the supply voltage among multiple discrete voltage levels within a single frame in response to an envelope signal. This means that in D-ET, the supply voltage varies at shorter time intervals than in APT.

### First Exemplary Embodiment

The following describes a first exemplary embodiment.

### 1.1 Circuit Configuration of Communication Device 7

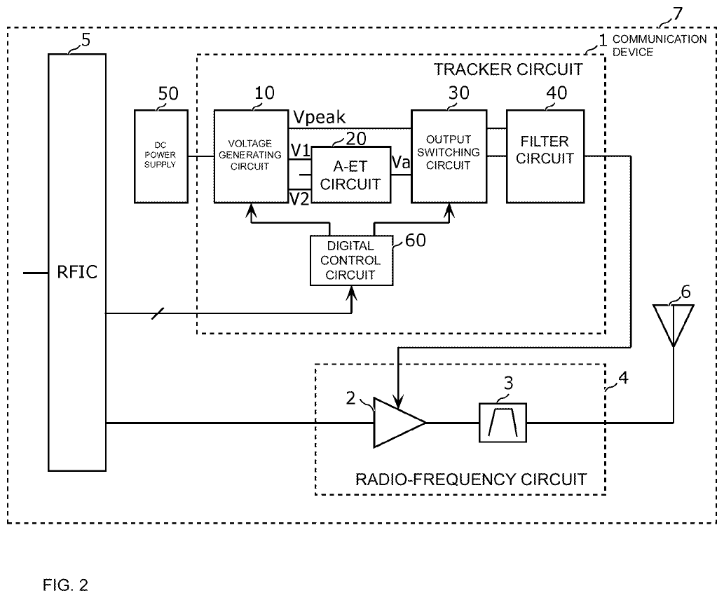

First, a circuit configuration of a communication device 7 according to the present embodiment will be described with reference to FIG. 2. FIG. 2 is a circuit configuration diagram of the communication device 7 according to the present embodiment.

FIG. 2 illustrates an exemplary circuit configuration. The communication device 7 can be implemented using any of various circuit implementations and circuit techniques. Hence, the description of the communication device 7 provided below is to provide exemplary aspects and should not be interpreted as limiting.

The communication device 7 according to the present embodiment corresponds to a user equipment (UE) for cellular networks (also referred to as mobile networks), and is typically, for example, a mobile phone, smartphone, tablet computer, or wearable device. The communication device 7 can be an Internet of Things (IoT) sensor device, medical/health care device, automobile, unmanned aerial vehicle (UAV) (drone), or automated guided vehicle (AGV). The communication device 7 operates as a base station (BS) in cellular networks in some exemplary aspects.

As illustrated in FIG. 2, the communication device 7 includes a tracker circuit 1, a radio-frequency circuit 4, a radio-frequency integrated circuit (RFIC) 5, an antenna 6, and a direct-current (DC) power supply 50.

The tracker circuit 1 is configured to supply a supply voltage to a power amplifier 2. Specifically, the tracker circuit 1 is configured to generate a supply voltage while switching between a constant voltage mode and the A-ET mode and supplies the generated supply voltage to the power amplifier 2. Mode switching is performed, for example, in units smaller than single-frame units (for example, subframes, slots, or symbols).

The constant voltage mode is an operating mode in which the supply voltage level remains constant. The constant voltage mode corresponds to the APT mode illustrated in FIG. 1A. Alternatively, the constant voltage mode can be viewed as the D-ET mode in which only one among the multiple discrete voltages is selectable. In the constant voltage mode, the voltage level remains constant within at least a single frame, but the voltage level can vary on a per-frame or larger basis in some exemplary aspects.

As illustrated in FIG. 2, the tracker circuit 1 includes a voltage generating circuit 10, an A-ET circuit 20, an output switching circuit 30, a filter circuit 40, and a digital control circuit 60.

The voltage generating circuit 10 is configured to generate a peak voltage Vpeak that is higher than the maximum voltage value of a continuously varying voltage Va generated by the A-ET circuit 20. In the present embodiment, the voltage generating circuit 10 is configured to receive an input voltage, generate the peak voltage Vpeak, and a first voltage V1 and a second voltage V2, output the peak voltage Vpeak to the output switching circuit 30, and output the first voltage V1 and the second voltage V2 to the A-ET circuit 20.

The first voltage V1 is equal to a magnitude obtained by subtracting the second voltage V2 from a third voltage V3, which is higher than the second voltage V2. As used herein, the third voltage V3 refers to the upper limit of the continuously varying voltage Va that can be supplied in the A-ET mode. As used herein, the second voltage V2 refers to the lower limit of the continuously varying voltage Va that can be supplied in the A-ET mode. Thus, the first voltage V1 corresponds to the difference between the upper and lower limits of the continuously varying voltage Va that can be supplied in the A-ET mode, in other words, the variation range of the continuously varying voltage Va supplied in the A-ET mode.

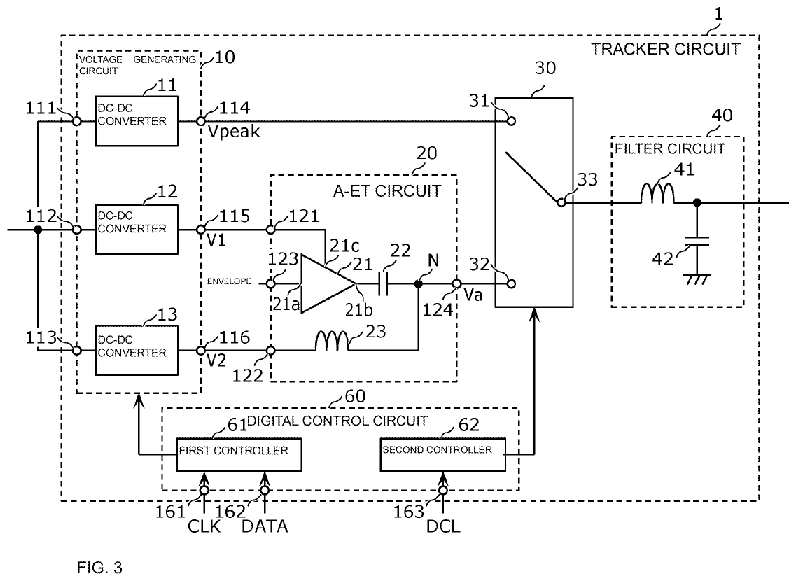

The voltage generating circuit 10 is configured to change the magnitude of the peak voltage Vpeak, the magnitude of the first voltage V1, and the magnitude of the second voltage V2, for example, in response to a control signal from the RFIC 5. The peak voltage Vpeak, the first voltage V1, and the second voltage V2 are DC voltages, each with a distinct voltage value (e.g., voltage level). The circuit configuration of the voltage generating circuit 10 will be described later with reference to FIG. 3.

The A-ET circuit 20 is configured to generate the continuously varying voltage Va. The voltage level of the continuously varying voltage Va continuously varies in response to the envelope signal. The continuously varying voltage Va varies to track the envelope of a modulated wave. In the present embodiment, the A-ET circuit 20 is able to generate the continuously varying voltage Va using the first voltage V1 and the second voltage V2 outputted from the voltage generating circuit 10 and the envelope signal. The circuit configuration of the A-ET circuit 20 will be described later with reference to FIG. 3.

The output switching circuit 30 is configured to receive the continuously varying voltage Va from the A-ET circuit 20 and the peak voltage Vpeak from the voltage generating circuit 10. Specifically, the output switching circuit 30 is configured to selectively output either the continuously varying voltage Va or the peak voltage Vpeak to the power amplifier 2. For example, the output switching circuit 30 is configured to output the continuously varying voltage Va to the power amplifier 2 when the envelope value is smaller than the threshold and to output the peak voltage Vpeak to the power amplifier 2 when the envelope value is greater than the threshold. As such, the output switching circuit 30 selects either the continuously varying voltage Va or the peak voltage Vpeak and supplies the selected voltage to the power amplifier 2. The circuit configuration of the output switching circuit 30 will be described later with reference to FIG. 3.

The filter circuit 40 is coupled between the output switching circuit 30 and the power amplifier 2. Incorporating the filter circuit 40 contributes to slowing down voltage changes when the output switching circuit 30 switches connections, thereby minimizing switching noise. The circuit configuration of the filter circuit 40 will be described later with reference to FIG. 3. It is noted that the filter circuit 40 is not included in the tracker circuit 1 in some exemplary aspects.

The digital control circuit 60 can be operated and configured to control the voltage generating circuit 10 and the output switching circuit 30 in response to digital control signals from the RFIC 5. Specifically, the digital control circuit 60 generates and outputs a control signal for controlling the magnitude of the voltage generated by the voltage generating circuit 10 and a control signal for controlling switches included in the output switching circuit 30. The circuit configuration of the digital control circuit 60 will be described later with reference to FIG. 3. It is noted that the digital control circuit 60 is not included in the tracker circuit 1 in some exemplary aspects.

The DC power supply 50 is configured to supply a DC voltage to the voltage generating circuit 10. For example, a rechargeable battery is used as the DC power supply 50. However, this is not to be interpreted as limiting. In the present embodiment, the DC voltage outputted by the DC power supply 50 corresponds to the input voltage to the tracker circuit 1.

The radio-frequency circuit 4 is configured to transfer radio-frequency signals between the RFIC 5 and the antenna 6. As illustrated in FIG. 2, the radio-frequency circuit 4 includes the power amplifier 2 and a filter 3.

The power amplifier 2 is coupled between the RFIC 5 and the filter 3. The power amplifier 2 is also coupled to the tracker circuit 1. The power amplifier 2 is configured to amplify radio-frequency signals received from the RFIC 5 using the supply voltage (the continuously varying voltage Va and the peak voltage Vpeak) received from the tracker circuit 1.

The filter 3 is coupled between the power amplifier 2 and the antenna 6. The filter 3 is a band pass filter that has a pass band including a particular band. It is be noted that the filter 3 is not included in the radio-frequency circuit 4 in some exemplary aspects.

The particular band represents a frequency band for communication systems that are built using radio access technologies (RAT), determined by, for example, standards organizations such as the 3rd Generation Partnership Project (3GPP, registered trademark) and the Institute of Electrical and Electronics Engineers (IEEE)). Examples of communication systems include a 5GNR system, an LTE system, and a Wireless Local Area Network (WLAN) system.

The RFIC 5 is an example of a signal processing circuit configured to process a radio-frequency signal. The RFIC 5 is coupled to the input terminal of the power amplifier 2. The RFIC 5 is configured to perform signal processing, for example up-conversion, on transmit signals inputted from a BBIC, which is not illustrated in the drawing, and output the radio-frequency transmit signals generated by the signal processing to a transmit path (specifically, to the power amplifier 2) in the radio-frequency circuit 4.

The RFIC 5 is an example of a control circuit. The RFIC 5 includes a control unit for controlling, for example, the tracker circuit 1 and the power amplifier 2. For example, the RFIC 5 outputs the envelope signal of the radio-frequency input signal obtained from the BBIC to the tracker circuit 1. The envelope signal can be used to select the voltage to be outputted by the tracker circuit 1.

The function of the control unit of the RFIC 5 is partially or entirely implemented outside the RFIC 5 in some exemplary aspects. In an example, the function of the control unit of the RFIC 5 is implemented in the BBIC or the tracker circuit 1. In some exemplary aspects, the control function of selecting the supply voltage described above is not provided by the RFIC 5, but by the tracker circuit 1.

The antenna 6 is configured to transmit radio-frequency signals inputted from the radio-frequency circuit 4. It is be noted that the antenna 6 is not included in the communication device 7 in some exemplary aspects.

The circuit configuration of the communication device 7 illustrated in FIG. 2 is provided for illustrative purposes, and this is not to be interpreted as limiting. For example, the communication device 7 includes a baseband signal processing circuit (BBIC) for performing signal processing using an intermediate frequency band that is lower than radio-frequency signals.

### 1.2 Circuit Configuration of Tracker Circuit 1

Next, a circuit configuration of the tracker circuit 1 will be described with reference to FIG. 3. FIG. 3 is a circuit configuration diagram of the tracker circuit 1 according to the present embodiment.

FIG. 3 illustrates an exemplary circuit configuration. The tracker circuit 1 is implemented using any of various circuit implementations and circuit techniques. Hence, the description of the tracker circuit 1 provided below should not be interpreted as limiting.

As described above, the tracker circuit 1 includes the voltage generating circuit 10, the A-ET circuit 20, the output switching circuit 30, the filter circuit 40, and the digital control circuit 60. In some exemplary aspects, the tracker circuit 1 does not include at least one of the filter circuit 40 and the digital control circuit 60. This configuration reduces the size of the tracker circuit 1.

The following individually describes a circuit configuration of the voltage generating circuit 10, a circuit configuration of the A-ET circuit 20, a circuit configuration of the output switching circuit 30, a circuit configuration of the filter circuit 40, and a circuit configuration of the digital control circuit 60.

### 1.2.1 Circuit Configuration of Voltage Generating Circuit 10

First, a circuit configuration of the voltage generating circuit 10 will be described with reference to FIG. 3.

As illustrated in FIG. 3, the voltage generating circuit 10 includes DC-DC converters 11 to 13, input terminals 111 to 113, and output terminals 114 to 116.

Each of the input terminals 111 to 113 is configured to receive an input voltage to the tracker circuit 1. Specifically, each of the input terminals 111 to 113 receives a DC voltage from the DC power supply 50 as an input voltage. The input terminal 111 is coupled to the DC-DC converter 11 inside the voltage generating circuit 10 and to the output terminal (not illustrated in the drawing) of the DC power supply 50 outside the voltage generating circuit 10. The input terminal 112 is coupled to the DC-DC converter 12 inside the voltage generating circuit 10 and to the output terminal (not illustrated in the drawing) of the DC power supply 50 outside the voltage generating circuit 10. The input terminal 113 is coupled to the DC-DC converter 13 inside the voltage generating circuit 10 and to the output terminal (not illustrated in the drawing) of the DC power supply 50 outside the voltage generating circuit 10. The input terminals 111 to 113 are integrated into a single terminal in an example. In some exemplary aspects, different voltages are input to at least two of the input terminals 111 to 113.

The output terminal 114 is configured to output the peak voltage Vpeak generated from the input voltage. Specifically, the output terminal 114 outputs the peak voltage Vpeak outputted from the DC-DC converter 11 to the output switching circuit 30. The output terminal 114 is coupled to the DC-DC converter 11 inside the voltage generating circuit 10 and to an input terminal 31 of the output switching circuit 30 outside the voltage generating circuit 10.

The output terminal 115 is configured to output the first voltage V1 generated from the input voltage. Specifically, the output terminal 115 outputs the first voltage V1 outputted from the DC-DC converter 12 to the A-ET circuit 20. The output terminal 115 is coupled to the DC-DC converter 12 inside the voltage generating circuit 10 and to an input terminal 121 of the A-ET circuit 20 outside the voltage generating circuit 10.

The output terminal 116 is configured to output the second voltage V2 generated from the input voltage. Specifically, the output terminal 116 outputs the second voltage V2 outputted from the DC-DC converter 13 to the A-ET circuit 20. The output terminal 116 is coupled to the DC-DC converter 13 inside the voltage generating circuit 10 and to an input terminal 122 of the A-ET circuit 20 outside the voltage generating circuit 10.

The DC-DC converter 11 is an example of a first converter. The DC-DC converter 11 is configured to convert the input voltage into the peak voltage Vpeak and output the peak voltage Vpeak to the output switching circuit 30. The DC-DC converter 11 is a single-input single-output buck-boost converter. The DC-DC converter 11 receives the output voltage of the DC power supply 50 as the input voltage, convert the received input voltage into the peak voltage Vpeak, and output the converted peak voltage Vpeak as the input voltage of the output switching circuit 30. The DC-DC converter 11 is able to change the magnitude of the peak voltage Vpeak, for example, in response to a control signal from the RFIC 5.

The DC-DC converter 12 is an example of a second converter. The DC-DC converter 12 is configured to convert the input voltage into the first voltage V1 and output the first voltage V1 to the A-ET circuit 20. The DC-DC converter 12 is a single-input single-output buck-boost converter. The DC-DC converter 12 receives the output voltage of the DC power supply 50 as the input voltage, converts the received input voltage into the first voltage V1, and outputs the converted first voltage V1 as the supply voltage to an amplifier 21 in the A-ET circuit 20. The DC-DC converter 12 is able to change the magnitude of the first voltage V1, for example, in response to a control signal from the RFIC 5.

The DC-DC converter 13 is an example of a third converter. The DC-DC converter 13 is configured to convert the input voltage into the second voltage V2 and output the second voltage V2 to the A-ET circuit 20. The DC-DC converter 13 is a single-input single-output buck-boost converter. The DC-DC converter 13 receives the output voltage of the DC power supply 50 as the input voltage, converts the received input voltage into the second voltage V2, and outputs the converted second voltage V2 as the supply voltage to a node N in the A-ET circuit 20. The DC-DC converter 13 is able to change the magnitude of the second voltage V2, for example, in response to a control signal from the RFIC 5.

At least one of the DC-DC converters 11 to 13 is a back converter or boost converter in some exemplary aspects.

The configuration of the voltage generating circuit 10 illustrated in FIG. 3 is provided for illustrative purposes and should not to be interpreted as limiting. For example, the output terminal 116, which outputs the second voltage V2 from the DC-DC converter 13, is coupled to the input terminal 122 in the A-ET circuit 20. However, this is not to be interpreted as limiting. In the present embodiment, the input terminal 122, the node N, and the output terminal 124 in the A-ET circuit 20 and the input terminal 32 of the output switching circuit 30 are at substantially the same potential. Thus, in some exemplary aspects, the output terminal 116 is coupled to the output terminal 124 of the A-ET circuit 20 or the input terminal 32 of the output switching circuit 30. The case in which the output terminal 116 is coupled to the input terminal 32 can be considered equivalent to the case in which the output terminal 116 is coupled to the A-ET circuit 20.

### 1.2.2 Circuit Configuration of A-ET Circuit 20

Next, a circuit configuration of the A-ET circuit 20 will be described with reference to FIG. 3.

As illustrated in FIG. 3, the A-ET circuit 20 includes input terminals 121 to 123, an output terminal 124, an amplifier 21, a capacitor 22, and an inductor 23.

The input terminal 121 is an example of a first input terminal. The input terminal 121 is configured to receive the first voltage V1 from the DC-DC converter 12. The input terminal 121 is coupled to a power supply terminal 21c of the amplifier 21 inside the A-ET circuit 20 and to the output terminal 115 outside the A-ET circuit 20.

The input terminal 122 is an example of a second input terminal. The input terminal 122 is configured to receive the second voltage V2 from the DC-DC converter 13. The input terminal 122 is coupled to the node N inside the A-ET circuit 20 and to the output terminal 116 outside the A-ET circuit 20. The input terminal 122 is coupled to the output terminal 124 via the node N.

The input terminal 123 is an example of a third input terminal. The input terminal 123 is configured to receive an envelope signal. The envelope signal is supplied from, for example, the RFIC 5. The input terminal 123 is coupled to an input terminal 21a of the amplifier 21 inside the A-ET circuit 20 and to the RFIC 5 outside the A-ET circuit 20. The configuration is not limited to any particular configurations, provided that the configuration enables reception of envelope signal input.

The output terminal 124 is an example of a first output terminal. The output terminal 124 is configured to output a continuously varying voltage. The output terminal 124 is coupled to the capacitor 22 insides the A-ET circuit 20 and to the input terminal 32 of the output switching circuit 30 outside the A-ET circuit 20.

The amplifier 21 is an envelope amplifier configured to receive the supplied first voltage V1 and amplify an envelope signal. The amplifier 21 includes the input terminal 21a, an output terminal 21b, and the power supply terminal 21c. The input terminal 21a is an example of a fourth input terminal. The input terminal 21a is coupled to the input terminal 123. The input terminal 21a is configured to receive an envelope signal through the input terminal 123. The output terminal 21b is an example of a second output terminal. The output terminal 21b is coupled to the capacitor 22. The output terminal 21b is configured to output an amplified envelope signal. The power supply terminal 21c is coupled to the input terminal 121. The power supply terminal 21c is configured to receive the first voltage V1 as the supply voltage. The amplifier 21 is configured to amplify the envelope signal inputted to the input terminal 21a using the first voltage V1 inputted to the power supply terminal 21c and outputs the amplified envelope signal from the output terminal 21b. For example, an envelope signal is a continuously varying analog voltage signal.

The capacitor 22 is provided in series in the path connecting the output terminal 21b to the output terminal 124 in the amplifier 21. The expression “A is provided in series in the path” refers to a situation in which two terminals of A are both coupled to the path. Specifically, one of the two electrical terminals of the capacitor 22 is coupled to the output terminal 21b of the amplifier 21, and the other of the two electrical terminals of the capacitor 22 is coupled to the output terminal 124. The capacitor 22 is a DC blocking capacitor. The capacitor 22 is able to minimize DC signals flowing from the DC-DC converter 13 and entering the amplifier 21.

The inductor 23 is provided in series in the path connecting the input terminal 122 to the output terminal 124. Specifically, one end of the inductor 23 is coupled to the input terminal 122, and the other end of the inductor 23 is coupled to the output terminal 124. More specifically, the other end of the inductor 23 and the other of the two electrical terminals of the capacitor 23 are coupled to the node N. The inductor 23 is able to minimize alternating-current (AC) signals flowing from the amplifier 21 and entering the DC-DC converter 13.

In the A-ET circuit 20, the node N is provided between the output terminal 21b of the amplifier 21 and the output terminal 124. Specifically, the node N is provided between the capacitor 22 and the output terminal 124. The node N is also positioned between the inductor 23 and the output terminal 124. The node N corresponds to the point at which the amplified envelope signal outputted from the amplifier 21 merges with the second voltage V2 supplied from the DC-DC converter 13 through the input terminal 122. Overall, in the A-ET circuit 20, the amplified envelope signal and the second voltage V2 are combined and output from the output terminal 124 to the output switching circuit 30.

The configuration of the A-ET circuit 20 illustrated in FIG. 3 is provided for illustrative purposes only. The circuit configuration of the A-ET circuit 20 is not limited to any particular configurations, provided that the A-ET circuit 20 is able to output a voltage signal that tracks the envelope of a modulated wave.

### 1.2.3 Circuit Configuration of Output Switching Circuit 30

Next, a circuit configuration of the output switching circuit 30 will be described with reference to FIG. 3.

The output switching circuit 30 is coupled between the voltage generating circuit 10 and the A-ET circuit 20, and the power amplifier 2. Specifically, the output switching circuit 30 is coupled between the output terminal 114 of the voltage generating circuit 10 and the output terminal 124 of the A-ET circuit 20, and the filter circuit 40.

The output switching circuit 30 is configured to switch between: (a) the connection between the voltage generating circuit 10 and the power amplifier 2 (the filter circuit 40), and (b) the connection between the A-ET circuit 20 and the power amplifier 2 (the filter circuit 40), in response to a signal supplied from the digital control circuit 60. The output switching circuit 30 is a single-pole double-throw (SPDT) switching circuit having one common terminal and two selection terminals. The common terminal can be exclusively coupled to either of the two selection terminals.

As illustrated in FIG. 3, the output switching circuit 30 has input terminals 31 and 32 and an output terminal 33.

The input terminal 31 corresponds to one of the selection terminals. The input terminal 31 is configured to receive the peak voltage Vpeak outputted from the voltage generating circuit 10. The input terminal 31 is coupled to the output terminal 114 of the voltage generating circuit 10.

The input terminal 32 corresponds to one of the selection terminals. The input terminal 32 is configured to receive the continuously varying voltage Va outputted from the A-ET circuit 20. The input terminal 32 is coupled to the output terminal 124 of the A-ET circuit 20.

The output terminal 33 corresponds to the common terminal. The output terminal 33 is configured to selectively supply either the peak voltage Vpeak or the continuously varying voltage Va. The output terminal 33 is coupled to the power amplifier 2 via the filter circuit 40. The output terminal 33 is connectable exclusively to one of the input terminals 31 and 32.

The configuration of the output switching circuit 30 illustrated in FIG. 3 is provided for illustrative purposes only. The configuration of the output switching circuit 30 is not limited to any particular configurations, provided that the peak voltage Vpeak or the continuously varying voltage Va can be selectively supplied to the power amplifier 2.

### 1.2.4 Circuit Configuration of Filter Circuit 40

Next, a circuit configuration of the filter circuit 40 will be described with reference to FIG. 3.

The filter circuit 40 is coupled between the output switching circuit 30 and the power amplifier 2. As illustrated in FIG. 3, the filter circuit 40 includes an inductor 41 and a capacitor 42.

The inductor 41 is coupled in series with the interconnection path (the supply path for the supply voltage) connecting the output switching circuit 30 and the power amplifier 2. Specifically, one end of the inductor 41 is coupled to the output terminal 33 of the output switching circuit 30 outside the filter circuit 40, and the other end of the inductor 41 is coupled to the power amplifier 2 outside the filter circuit 40 (the tracker circuit 1). The other end of inductor 41 is coupled to one of the two electrical terminals of the capacitor 42 inside the filter circuit 40.

The capacitor 42 is coupled between the interconnection path (the supply path for the supply voltage) connecting the output switching circuit 30 and the power amplifier 2 and ground. Specifically, one of the two electrical terminals of the capacitor 42 is coupled to the interconnection path connecting the output switching circuit 30 and the power amplifier 2, and the other of the two electrical terminals of the capacitor 42 is grounded.

The configuration of the filter circuit 40 illustrated in FIG. 3 is provided for illustrative purposes only. The circuit configuration of the filter circuit 40 is not limited to any particular configurations, provided that the filter circuit 40 is able to remove noises caused by, for example, the output switching circuit 30.

### 1.2.5 Circuit Configuration of Digital Control Circuit 60

Next, a circuit configuration of the digital control circuit 60 will be described with reference to FIG. 3. The digital control circuit 60 includes a first controller 61, a second controller 62, and control terminals 161 to 163.

The first controller 61 is configured to generate a control signal for controlling the voltage generating circuit 10 by processing a serial data signal supplied from the RFIC 5 through the control terminals 161 and 162. For example, a source-synchronous digital control signal can be used as the serial data signal. The characteristics such as magnitude of the voltages generated by the DC-DC converters 11 to 13 included in the voltage generating circuit 10 can be controlled via the control signal from the first controller 61.

A clock-embedded digital control signal is used as the serial data signal in an example. The first controller 61 also generates a control signal for controlling the output switching circuit 30 in an example.

The second controller 62 is configured to generate a control signal for controlling the output switching circuit 30 by processing a parallel data signal supplied from the RFIC 5 through the control terminal 163. For example, a digital control logic/line signal (DCL) can be used as the parallel data signal. The DCL signal (DCL) can be generated by the RFIC 5, using the envelope signal of a radio-frequency signal. Switches S81 to S87 included in the output switching circuit 30 can be controlled to open or close via the control signal from the second controller 62.

According to an exemplary aspect, the DCL signal (DCL) is a 1-bit signal. Whether the voltage selected as the supply voltage is the peak voltage Vpeak or the continuously varying voltage Va is indicated by a 1-bit signal. For example, “0” indicates the peak voltage Vpeak, and “1” indicates the continuously varying voltage Va.

In the present embodiment, the parallel data signal used to control the output switching circuit 30 is not limited to a DCL signal.

### 1.3 Voltage Supply Method

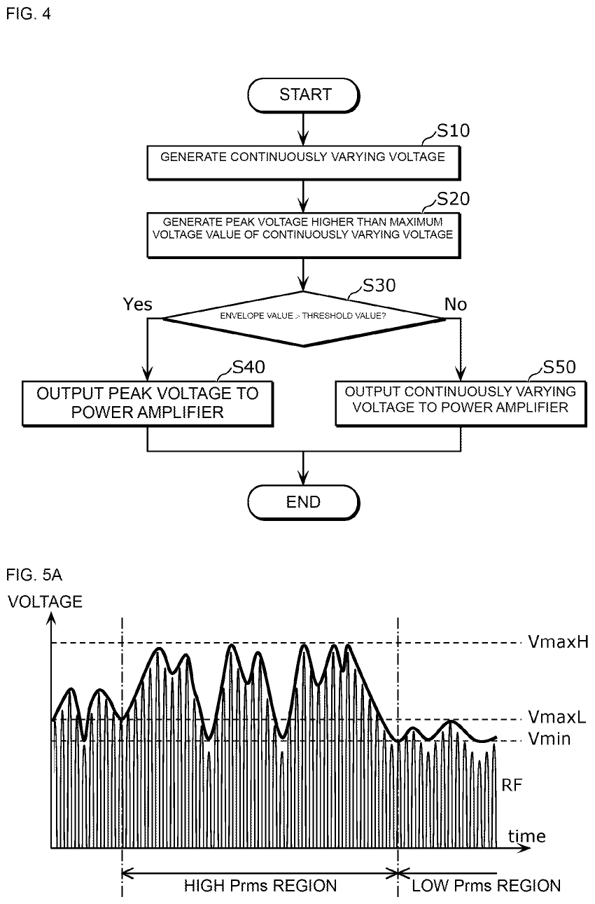

Next, a voltage supply method according to the present embodiment will be described with reference to FIG. 4. FIG. 4 is a flowchart illustrating the voltage supply method according to the present embodiment.

First, the continuously varying voltage Va is generated using the A-ET circuit 20 (S10). Specifically, the first voltage V1 and the second voltage V2 are generated using the voltage generating circuit 10, and the continuously varying voltage Va is then generated based on the first voltage V1 and the second voltage V2.

Next, the peak voltage Vpeak higher than the maximum voltage value of the continuously varying voltage Va is generated using the voltage generating circuit 10 (S20).

Next, the envelope value is compared to a threshold (S30). This comparison is performed within a single frame, for example, by the second controller 62 of the digital control circuit 60, or the RFIC 5. In some exemplary aspects, this comparison is performed at a timing equivalent to the timing when the voltage level can be changed in the D-ET mode illustrated in FIG. 1C. For example, the comparison is performed multiple times within a single frame. The envelope value corresponds to the signal level of the envelope signal.

When the envelope value is greater than the threshold (Yes in S30), the peak voltage Vpeak is output to the power amplifier 2 using the output switching circuit 30 (S40). Specifically, the output switching circuit 30 selects the peak voltage Vpeak between the peak voltage Vpeak and the continuously varying voltage Va and outputs the peak voltage Vpeak to the power amplifier 2.

When the envelope value is smaller than the threshold (No in S30), the continuously varying voltage Va is output to the power amplifier 2 using the output switching circuit 30 (S50). Specifically, the output switching circuit 30 selects the continuously varying voltage Va between the peak voltage Vpeak and the continuously varying voltage Va and outputs the continuously varying voltage Va to the power amplifier 2.

By selecting a voltage using the envelope value in this manner, the power amplifier 2 switches between the constant voltage mode and the A-ET mode. Depending on the envelope value, the constant voltage mode and the A-ET mode are switched multiple times within a single frame in some exemplary aspects.

In some exemplary aspects, the comparison of the envelope value to the threshold (S30) is not performed within a single frame; the comparison is performed in frame units or larger units in an example. In some exemplary aspects, the constant voltage mode and the A-ET mode are switched in frame units or larger units.

### 1.4 Mode Switching of Tracker Circuit 1

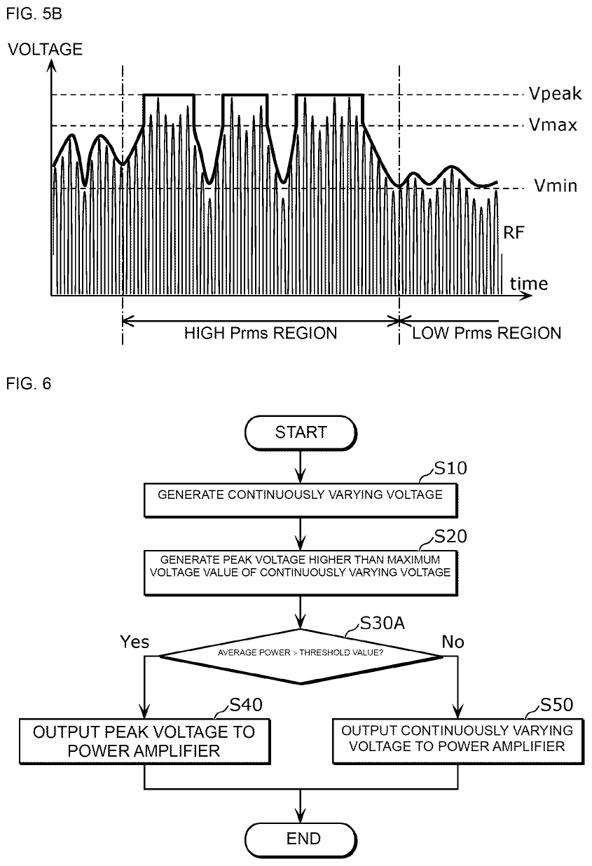

Mode switching in the tracker circuit 1 configured as described above will be described with reference to FIGS. 5A and 5B.

First, the case in which operation is performed only in the A-ET mode without mode switching will be described with reference to FIG. 5A. FIG. 5A is a graph that plots the voltage supplied to a power amplifier by a tracker circuit according to a comparative example. In FIG. 5A, the horizontal axis represents time, and the vertical axis represents voltage. The thick solid line represents the supply voltage, and the thin solid line (e.g., waveform) represents the modulated wave.

The tracker circuit according to the comparative example is configured to operate only in the A-ET mode, without the constant voltage mode of the tracker circuit 1 according to the present embodiment. In other words, the tracker circuit according to the comparative example corresponds to the tracker circuit 1 illustrated in FIG. 3 in a state in which the input terminal 32 and the output terminal 33 of the output switching circuit 30 are constantly coupled. In the following, an operation of the A-ET mode will be described with reference to the configuration of the tracker circuit 1 illustrated in FIG. 3.

In the A-ET mode, the power amplifier 2 is supplied with the continuously varying voltage Va that varies within a voltage value range from a minimum value Vmin and a maximum value VmaxH for a period of higher average power (a high Prms region in FIG. 5A). The power amplifier 2 is supplied with the continuously varying voltage Va that varies within a voltage value range from the minimum value Vmin and a maximum value VmaxL for a period of lower average power (a low Prms region in FIG. 5A). As used herein, the maximum values VmaxH and VmaxL represent the magnitudes that correspond to the peak voltages within the respective periods. The minimum value Vmin is the same in the high and low Prms regions in the above example, but the minimum value Vmin is differ between the high and low Prms regions in some exemplary aspects.

As described above, in the A-ET mode, the variation range of the continuously varying voltage Va can be changed based on the average power in single-frame units or larger units. The variation range can be changed by the voltage generating circuit 10, in response to the digital control signal from the RFIC 5.

The minimum value Vmin corresponds to the magnitude of the second voltage V2 inputted to the input terminal 122 (the node N) in the A-ET circuit 20. Because the second voltage V2 is a voltage generated and output by the DC-DC converter 13, the minimum value Vmin, which corresponds to the magnitude of the second voltage V2, can be changed by controlling the operation of the DC-DC converter 13.

The maximum values VmaxH and VmaxL correspond to the magnitude of the third voltage V3, which is higher than the second voltage V2. The difference between the maximum value VmaxH or VmaxL and the minimum value Vmin, that is, the variation range of the continuously varying voltage Va, corresponds to the magnitude of the first voltage V1 inputted to the input terminal 121 of the A-ET circuit 20 (the power supply terminal 21c of the amplifier 21). Because the first voltage V1 is the voltage generated and output by the DC-DC converter 12, the magnitude of the first voltage V1, which is represented by VmaxH−Vmin or VmaxL−Vmin, can be changed by controlling the operation of the DC-DC converter 12.

As illustrated in FIG. 5A, the efficiency of the amplifier 21 decreases in the high Prms region, because the variation range (VmaxH−Vmin) of the continuously varying voltage Va is larger in the high Prms region than in the low Prms region.

By contrast, the tracker circuit 1 according to the present embodiment suppresses the variation range of the continuously varying voltage Va supplied in the A-ET mode, as illustrated in FIG. 5B. FIG. 5B is a graph that plots the voltage supplied to the power amplifier 2 by the tracker circuit 1 according to the present embodiment. In FIG. 5B, the horizontal axis represents time, and the vertical axis represents voltage. The thick solid line represents the supply voltage, and the thin solid line (waveform) represents the modulated wave.

As illustrated in FIG. 5B, in the tracker circuit 1 according to the present embodiment, the variation range of the continuously varying voltage Va is suppressed, and the maximum value Vmax of the continuously varying voltage Va is smaller than the peak voltage Vpeak. The tracker circuit 1 is configured to supply the peak voltage Vpeak to the power amplifier 2 in place of the continuously varying voltage Va for periods when a voltage higher than the maximum value Vmax is required.

In the present embodiment, as illustrated in FIG. 4, the A-ET mode and the constant voltage mode are switched in accordance with the comparison result of the envelope value to the threshold. This configuration suppresses the variation range of the continuously varying voltage Va and enables supply of the peak voltage Vpeak higher than the maximum value Vmax of the continuously varying voltage Va. The threshold represents the envelope value corresponding to the maximum value Vmax of the continuously varying voltage Va illustrated in FIG. 5B. The threshold is, for example, but not limited to, a fixed value. For example, the threshold is variable in single-frame units or larger units.

In the tracker circuit 1, the A-ET circuit 20 can operate in a low power consumption mode during the period in which the peak voltage Vpeak is supplied. In some exemplary aspects, the first voltage V1, which is supplied to the power supply terminal 21c of the amplifier 21, is set equal to the second voltage V2. Setting the first voltage V1 and the second voltage V2 in this manner causes the amplifier 21 to become practically deactivated. This configuration reduces power consumption, thereby increases efficiency.

### 1.5 Effects

As described above, the tracker circuit 1 according to the present embodiment includes the A-ET circuit 20 configured to generate the continuously varying voltage Va, the voltage generating circuit 10 configured to generate the peak voltage Vpeak that is higher than the maximum voltage value of the continuously varying voltage Va, and the output switching circuit 30 configured to receive the continuously varying voltage Va and the peak voltage Vpeak. The output switching circuit 30 is configured to output the continuously varying voltage Va to the power amplifier 2 when the envelope value is smaller than the threshold. The output switching circuit 30 is configured to output the peak voltage Vpeak to the power amplifier 2 when the envelope value is greater than the threshold.

This configuration suppresses the variation range of the continuously varying voltage Va and improves the tracker efficiency. While the average power mostly remains within the range in which the envelope value is smaller than the threshold, the continuously varying voltage Va is supplied to the power amplifier 2. As such, the power-added efficiency of the power amplifier 2 is increased. While the envelope value is greater than the threshold, the peak voltage Vpeak is supplied. As such, the linear performance of the power amplifier 2 can be ensured.

In an example, the A-ET circuit 20 includes the amplifier 21 configured to receive the first voltage V1 and amplify the envelope signal. The A-ET circuit 20 is configured to generate the continuously varying voltage Va by combining the envelope signal amplified by the amplifier 21 with the second voltage V2.

With this configuration, the continuously varying voltage Va can be suitably generated based on the envelope signal. As such, the power-added efficiency of the power amplifier 2 is increased.

In an example, according to another aspect, the A-ET circuit 20 includes the input terminal 121 configured to receive the first voltage V1, the input terminal 122 configured to receive the second voltage V2, the input terminal 123 configured to receive the envelope signal, the output terminal 124 configured to output the continuously varying voltage Va, and the amplifier 21 including the power supply terminal 21c coupled to the input terminal 121, the input terminal 21a coupled to the input terminal 123, and the output terminal 21b coupled to the output terminal 124. The input terminal 122 is coupled to the output terminal 124.

With this configuration, the continuously varying voltage Va can be suitably generated based on the envelope signal. As such, the power-added efficiency of the power amplifier 2 is increased.

In an example, the A-ET circuit 20 includes the capacitor 22 provided in series in the path connecting the output terminal 124 and the output terminal 21b.

This configuration minimizes the DC component flowing to the output terminal 124 through the input terminal 122 and entering the amplifier 21. As such, the power-added efficiency of the power amplifier 2 is improved.

In an example, the voltage generating circuit 10 includes the DC-DC converter 11 configured to convert the input voltage into the peak voltage Vpeak and output the peak voltage Vpeak to the output switching circuit 30, the DC-DC converter 12 configured to convert the input voltage into the first voltage V1 and output the first voltage V1 to the A-ET circuit 20, and the DC-DC converter 13 configured to convert the input voltage into the second voltage V2 and output the second voltage V2 to the A-ET circuit 20.

Because with this configuration, the peak voltage Vpeak, the first voltage V1, and the second voltage V2 are generated individually by the three DC-DC converters 11 to 13, the peak voltage Vpeak, the first voltage V1, and the second voltage V2 can be generated with high precision. As a result, the peak voltage Vpeak and the continuously varying voltage Va can be suitably generated. As such, the power-added efficiency of the power amplifier 2 is increased.

In an example, the first voltage V1 is equal to the magnitude obtained by subtracting the second voltage V2 from the third voltage V3, which is higher than the second voltage V2. The peak voltage Vpeak is higher than the third voltage V3.

With this configuration, the supply voltage corresponding to the variation range of the continuously varying voltage Va can be supplied to the amplifier 21. As such, the degradation of efficiency of the amplifier 21 is suppressed.

In an example, the tracker circuit 1 includes the control terminal 163 configured to receive a parallel data signal for controlling the output switching circuit 30.

With this configuration, switching between the A-ET mode and the constant voltage mode can be performed rapidly. For example, switching within a single frame can be easily achieved.

In an example, the filter circuit 40 coupled between the output switching circuit 30 and the power amplifier 2 is further included.

This configuration contributes to slowing down voltage changes when the output switching circuit 30 switches connections, thereby minimizing switching noise.

The communication device 7 according to the present embodiment includes the tracker circuit 1, the RFIC 5 configured to process radio-frequency signals, and the radio-frequency circuit 4 that includes the power amplifier 2 and is configured to transfer radio-frequency signals between the RFIC 5 and the antenna 6.

This configuration suppresses the variation range of the continuously varying voltage Va and improves the tracker efficiency, similarly to the tracker circuit 1 described above. While the average power mostly remains within the range in which the envelope value is smaller than the threshold, the continuously varying voltage Va is supplied to the power amplifier 2. As such, the power-added efficiency of the power amplifier 2 is increased. While the envelope value is greater than the threshold, the peak voltage Vpeak is supplied. As such, the linear performance of the power amplifier 2 can be ensured.

The voltage supply method according to the present embodiment includes: generating the continuously varying voltage Va (S10); generating the peak voltage Vpeak that is higher than the maximum voltage value of the continuously varying voltage Va (S20); and when the envelope value is smaller than the threshold (No in S30), outputting the continuously varying voltage Va to the power amplifier 2 (S50), and when the envelope value is greater than the threshold (Yes in S30), outputting the peak voltage Vpeak to the power amplifier 2 (S40).

This configuration suppresses the variation range of the continuously varying voltage Va and improves the tracker efficiency, similarly to the tracker circuit 1 described above. While the average power mostly remains within the range in which the envelope value is smaller than the threshold, the continuously varying voltage Va is supplied to the power amplifier 2. As such, the power-added efficiency of the power amplifier 2 is increased. While the envelope value is greater than the threshold, the peak voltage Vpeak is supplied. As such, the linear performance of the power amplifier 2 can be ensured.

### 1.6 Modification

Next, a tracker circuit, a communication device, and a voltage supply method according to a modification of the present embodiment will be described.

The present modification differs from the first exemplary embodiment mainly in that mode switching is performed based on the average power instead of the envelope value. The following describes the tracker circuit, the communication device, and the voltage supply method according to the present modification, primarily focusing on features that differ from the first exemplary embodiment, and descriptions of common features will not be repeated or will be simplified.

For example, the circuit configuration of the tracker circuit and the communication device according to the present modification is identical to the configuration in the first exemplary embodiment, and the description of the configuration will not be repeated. In the following, the voltage supply method according to the present modification will be described with reference to FIG. 6. FIG. 6 is a flowchart illustrating the voltage supply method according to the present modification.

First, the continuously varying voltage Va is generated using the A-ET circuit 20 (S10). Specifically, the first voltage V1 and the second voltage V2 are generated using the voltage generating circuit 10, and the continuously varying voltage Va is then generated based on the first voltage V1 and the second voltage V2.

Next, the peak voltage Vpeak higher than the maximum voltage value of the continuously varying voltage Va is generated using the voltage generating circuit 10 (S20).

Next, the average power is compared to a threshold (S30). This comparison is performed within a single frame, for example, by the second controller 62 of the digital control circuit 60, or the RFIC 5. In some exemplary aspects, this comparison is performed at a timing equivalent to the timing when the voltage level can be changed in the D-ET mode illustrated in FIG. 1C. For example, the comparison is performed multiple times within a single frame.

When the average power is greater than the threshold (Yes in S30A), the peak voltage Vpeak is output to the power amplifier 2 using the output switching circuit 30 (S40). Specifically, the output switching circuit 30 selects the peak voltage Vpeak between the peak voltage Vpeak and the continuously varying voltage Va and outputs the peak voltage Vpeak to the power amplifier 2.

When the average power is smaller than the threshold (No in S30A), the continuously varying voltage Va is output to the power amplifier 2 using the output switching circuit 30 (S50). Specifically, the output switching circuit 30 selects the continuously varying voltage Va between the peak voltage Vpeak and the continuously varying voltage Va and outputs the continuously varying voltage Va to the power amplifier 2.

By selecting a voltage using the average power in this manner, the power amplifier 2 switches between the constant voltage mode and the A-ET mode. Depending on the average power, the constant voltage mode and the A-ET mode are switched multiple times within a single frame in some exemplary aspects.

As described above, by switching between the constant voltage mode and the A-ET mode based on the average power within a single frame, the supply voltage as illustrated by the thick line in FIG. 5B can be supplied to the power amplifier 2, similarly to the first exemplary embodiment. As a result, the tracker efficiency is increased, similar to the first exemplary embodiment.

As described above, the tracker circuit 1 according to the present modification includes the A-ET circuit 20 configured to generate the continuously varying voltage Va, the voltage generating circuit 10 configured to generate the peak voltage Vpeak that is higher than the maximum voltage value of the continuously varying voltage Va, and the output switching circuit 30 configured to receive the continuously varying voltage Va and the peak voltage Vpeak. The output switching circuit 30 is configured to output the continuously varying voltage Va to the power amplifier 2 when the average power within a single frame is smaller than the threshold. The output switching circuit 30 is configured to output the peak voltage Vpeak to the power amplifier 2 when the average power within a single frame is greater than the threshold.

This configuration suppresses the variation range of the continuously varying voltage Va and improves the tracker efficiency. While the average power mostly remains within the range in which the average power is smaller than the threshold, the continuously varying voltage Va is supplied to the power amplifier 2. As such, the power-added efficiency of the power amplifier 2 is increased. While the average power is greater than the threshold, the peak voltage Vpeak is supplied. As such, the linear performance of the power amplifier 2 can be ensured.

The voltage supply method according to the present modification includes: generating the continuously varying voltage Va (S10); generating the peak voltage Vpeak that is higher than the maximum voltage value of the continuously varying voltage Va (S20); and when the average power within a single frame is smaller than the threshold (No in S30A), outputting the continuously varying voltage Va to the power amplifier 2 (S50), and when the average power within a single frame is greater than the threshold (Yes in S30A), outputting the peak voltage Vpeak to the power amplifier 2 (S40).

This configuration suppresses the variation range of the continuously varying voltage Va and improves the tracker efficiency. While the average power mostly remains within the range in which the average power is smaller than the threshold, the continuously varying voltage Va is supplied to the power amplifier 2. As such, the power-added efficiency of the power amplifier 2 is increased. While the average power is greater than the threshold, the peak voltage Vpeak is supplied. As such, the linear performance of the power amplifier 2 can be ensured.

### 1.7 Module Configuration

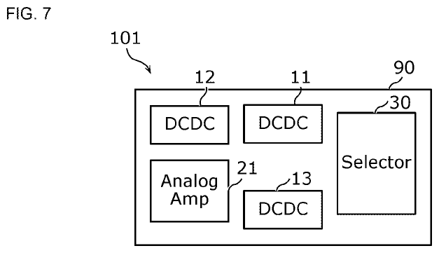

Next, a configuration of a module (tracker module) including the tracker circuit 1 according to the present embodiment will be described with reference to FIG. 7.

FIG. 7 is a plan view of an exemplary layout of circuit elements of the tracker circuit 1 according to the present embodiment. FIG. 7 illustrates an exemplary layout, and the circuit elements included in the tracker circuit 1 can be arranged in various layout configurations. Hence, the layout description provided below should not be interpreted as limiting.

As illustrated in FIG. 7, a tracker module 101 includes circuit elements included in the circuit configuration of the tracker circuit 1 illustrated in FIGS. 2 and 3, and a module substrate 90. Although not illustrated in the drawing, the tracker module 101 includes a resin member, an external connection terminal, and a shielding member in some exemplary aspects.

The module substrate 90 is a substrate on which the circuit elements constituting the tracker circuit 1 are mounted. As the module substrate 90, for example, a low temperature co-fired ceramic (LTCC) substrate that has a layered structure composed of multiple dielectric layers, a high temperature co-fired ceramic (HTCC) substrate, a component-embedded substrate, a substrate including a redistribution layer (RDL) (for example, an LTCC substrate including an RDL), or a printed-circuit board can be used.

In the present embodiment, the circuit elements are disposed on one of the major surfaces of the module substrate 90. In some exemplary aspects, the tracker module 101 is a single-sided mounting module with all circuit elements disposed on one side of the substrate. The tracker module 101 is a double-sided mounting module with circuit elements disposed on both sides of the substrate in some exemplary aspects. In an example, the DC-DC converters 11 to 13, the amplifier 21, and the output switching circuit 30 are disposed on a major surface of the module substrate 90.

The DC-DC converters 11 to 13, the amplifier 21, and the output switching circuit 30 are formed by individual integrated circuits, and the integrated circuits are disposed on the major surface of the module substrate 90. The integrated circuits are semiconductor integrated circuits (ICs) that are made, for example, using complementary metal oxide semiconductor (CMOS). Specifically, the semiconductor ICs are manufactured using Si substrates or silicon on insulator (SOI) substrates. In some exemplary aspects, the integrated circuits are made of at least one of GaAs, SiGe, and GaN. The semiconductor material for the ICs is not limited to the materials mentioned above.

As described above, the first voltage V1 generated by the DC-DC converter 12 can be supplied to the amplifier 21. By contrast, the peak voltage Vpeak generated by the DC-DC converter 11 can be supplied to the output switching circuit 30. For this reason, the DC-DC converter 12 and the amplifier 21 are positioned close to each other, and the DC-DC converter 11 and the output switching circuit 30 are positioned close to each other, as illustrated in FIG. 7. This configuration shortens the interconnection paths for voltage supply, thereby reducing parasitic capacitance and parasitic inductance.

Specifically, the distance between the DC-DC converter 12 and the amplifier 21 is shorter than the distance between the DC-DC converter 12 and the output switching circuit 30. The distance between the DC-DC converter 11 and the output switching circuit 30 is shorter than the distance between the DC-DC converter 11 and the amplifier 21. According to an exemplary aspect, the term “distance between A and B” refers to the shortest distance, specifically the minimal length among the lengths of multiple line segments that connect any given point on the contour of A in a plan view to any given point on the contour of B in the plan view.

The third voltage V3 generated by the DC-DC converter 13 can be supplied to the path connecting the output terminal 21b of the amplifier 21 to the input terminal 32 of the output switching circuit 30. For this reason, regarding the DC-DC converter 13, the DC-DC converters 11 and 13 are disposed between the amplifier 21 and the output switching circuit 30 in a plan view, as illustrated in FIG. 7. This configuration shortens the interconnection paths for voltage supply, thereby reducing parasitic capacitance and parasitic inductance. The term “C disposed between A and B” refers to a situation in which at least one of a vast number of line segments each connecting any given point within A to any given point within B passes through any given point within C.

When the DC-DC converters 11 to 13 are magnetic converters that include inductors, the inductors are not mounted on the module substrate 90 in some exemplary aspects. For example, the DC-DC converters 11 to 13 disposed at the module substrate 90 do not include all of the circuit elements such as switches, capacitors, and inductors that constitute the DC-DC converters 11 to 13. The same applies to the other circuits including the A-ET circuit 20. In some exemplary aspects, only one or some of the circuit elements that constitute each circuit are disposed at the module substrate 90, while the other circuit elements are provided outside the module substrate 90.

In FIG. 7, the capacitor 22 and the inductor 23 included in the A-ET circuit 20, the inductor 41 and the capacitor 42 included in the filter circuit 40, and the first controller 61 and the second controller 62 included in the digital control circuit 60 are not illustrated. For example, the capacitors 22 and 42 and the inductors 23 and 41 are formed as surface mount devices (SMDs) such as chip capacitors and chip inductors, or integrated passive devices (IPDs) and mounted at the module substrate 90. In some exemplary aspects, at least one of the capacitors 22 and 42 and the inductors 23 and 41 are formed by, for example, a wiring pattern provided at the module substrate 90. The first controller 61 and the second controller 62 are formed by integrated circuits and mounted at the module substrate 90. In some exemplary aspects, the first controller 61 and the second controller 62 are provided in the same integrated circuit as any of the DC-DC converters 11 to 13, the amplifiers 21, and the output switching circuit 30.

### Second Exemplary Embodiment

Next, a second exemplary embodiment will be described.

The second exemplary embodiment differs from the first exemplary embodiment primarily in that the voltage generating circuit includes a switched capacitor circuit in place of three DC-DC converters. The following primarily describes features that differ from the first exemplary embodiment, and descriptions of common features will not be repeated or will be simplified.

A communication device according to the present embodiment is identical to the communication device 7 according to the first exemplary embodiment, except that the communication device according to the present embodiment includes a tracker circuit 1A in place of a tracker circuit 1. The illustration and description of the communication device will not be repeated. A voltage supply method according to the present embodiment is also identical to the voltage supply method according to the first exemplary embodiment, and the illustration and description of the voltage supply method will not be repeated.

### 2.1 Circuit Configuration of Tracker Circuit 1A

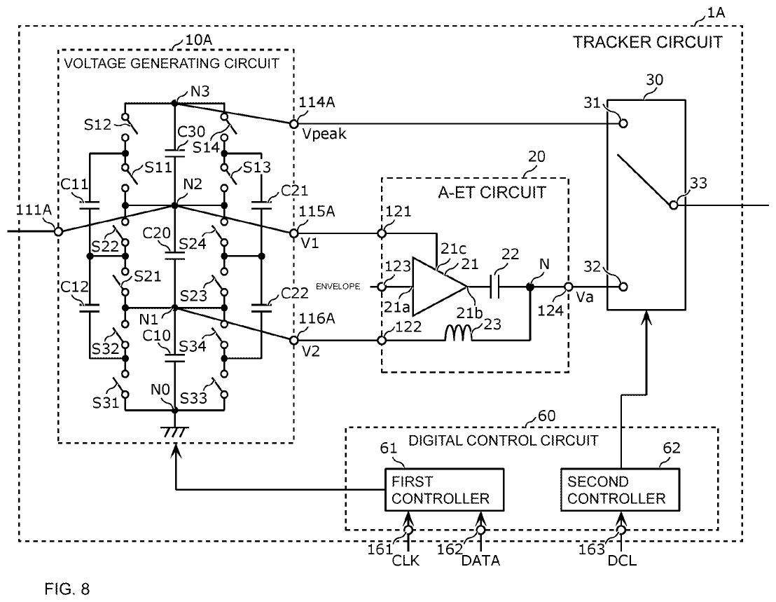

FIG. 8 is a circuit configuration diagram of the tracker circuit 1A according to the present embodiment. FIG. 8 illustrates an exemplary circuit configuration. In some exemplary aspects, the tracker circuit 1A is implemented using any of various circuit implementations and circuit techniques. Hence, the description of the tracker circuit 1A provided below should not be interpreted as limiting.

As illustrated in FIG. 8, the tracker circuit 1A is identical to the tracker circuit 1 according to the first exemplary embodiment, except that the tracker circuit 1A includes a voltage generating circuit 10A in place of the voltage generating circuit 10 and does not include the filter circuit 40. Similarly to the first exemplary embodiment, in some exemplary aspects, the tracker circuit 1A includes the filter circuit 40.

The voltage generating circuit 10A is configured to generate a peak voltage Vpeak that is higher than the maximum voltage value of a continuously varying voltage Va generated by the A-ET circuit 20. In the present embodiment, the voltage generating circuit 10A is configured to receive an input voltage, generate the peak voltage Vpeak, and a first voltage V1 and a second voltage V2, output the peak voltage Vpeak to the output switching circuit 30, and output the first voltage V1 and the second voltage V2 to the A-ET circuit 20.

In the present embodiment, the voltage generating circuit 10A includes a switched capacitor circuit. The switched capacitor circuit is configured to generate and output multiple discrete voltages including the peak voltage Vpeak, the first voltage V1, and the second voltage V2. In the present embodiment, the switched capacitor circuit is able to generate and output multiple discrete voltages based on the input voltage supplied from the DC power supply 50.

### 2.2 Circuit Configuration of Voltage Generating Circuit 10A (Switched Capacitor Circuit)

Next, a circuit configuration of the voltage generating circuit 10A will be described with reference to FIG. 8. The voltage generating circuit 10A has a ladder-type switched-capacitor circuit configuration. Specifically, the voltage generating circuit 10A includes capacitors C10, C20, C30, C11, C12, C21, and C22, switches S11 to S14, S21 to S24, and S31 to S34, an input terminal 111A, and output terminals 114A to 116A. Energy and charge can be input from the DC power supply 50 through the input terminal 111A to one of the nodes N1 to N3, and then directed from the nodes N1, N2, and N3 through the output terminals 114A to 116A to the A-ET circuit 20 and the output switching circuit 30.

The input terminal 111A is configured to receive the input voltage. Specifically, the input terminal 111A can be used to receive the input voltage from the DC power supply 50 to the tracker circuit 1. Specifically, the input terminal 111A is coupled to the output terminal (not illustrated) of the DC power supply 50 outside the voltage generating circuit 10A and to the node N2 inside the voltage generating circuit 10A. In some exemplary aspects, the input terminal 111A is coupled to the node N1 or N3.

The output terminal 114A is configured to output the peak voltage Vpeak, which is one of multiple discrete voltages. Specifically, the output terminal 114A can be used to supply the peak voltage Vpeak to the output switching circuit 30. The output terminal 114A is coupled to the input terminal 31 of the output switching circuit 30 outside the voltage generating circuit 10A and to the node N3 inside the voltage generating circuit 10A.

The output terminal 115A is configured to output the first voltage V1, which is one of multiple discrete voltages. Specifically, the output terminal 115A can be configured to supply the first voltage V1 to the amplifier 21 of the A-ET circuit 20. The output terminal 115A is coupled to the input terminal 121 of the A-ET circuit 20 outside the voltage generating circuit 10A and to the node N2 inside the voltage generating circuit 10A. In some exemplary aspects, the output terminal 115A is integrated with the input terminal 111A.

The output terminal 116A is configured to output the second voltage V2, which is one of multiple discrete voltages. Specifically, the output terminal 116A can be used to supply the second voltage V2 to the A-ET circuit 20. The output terminal 116A is coupled to the input terminal 122 of the A-ET circuit 20 outside the voltage generating circuit 10A and to the node N1 inside the voltage generating circuit 10A.

The peak voltage Vpeak, the first voltage V1, and the second voltage V2 can be generated based on the input voltage. The peak voltage Vpeak, the first voltage V1, the second voltage V2 decrease in voltage level in this order presented. In other words, the second voltage V2 corresponds to the lowest level, and the peak voltage Vpeak corresponds to the highest level. The peak voltage Vpeak, the first voltage V1, the second voltage V2 are set at regular intervals. In other words, for example, the difference between the first voltage V1 and the second voltage V2 (V1−V2) is equal to the difference between the peak voltage Vpeak and the first voltage V1 (Vpeak−V1). In the present embodiment, the first voltage V1 is equal to the input voltage.

The capacitors C11, C12, C21, and C22 are flying capacitors (also referred to as transfer capacitors). The capacitors C11, C12, C21, and C22 can be used to increase and/or decrease the input voltage. More specifically, the capacitors C11, C12, C21, and C22 are configured to transfer charge between the capacitors C11, C12, C21, and C22 and the nodes N3 to N1 to maintain Vpeak, V1, and V2 at the nodes N3 to N1 in a manner that satisfies the following conditions: (Vpeak−V1):(V1−V2):(V2−VG)=1:1:1, and Vpeak>V1>V2>VG. VG represents the ground potential.

One of the two electrical terminals of the capacitor C11 is coupled to one end of the switch S11 and one end of the switch S12. The other of the two electrical terminals of the capacitor C11 is coupled to one end of the switch S21 and one end of the switch S22.

One of the two electrical terminals of the capacitor C12 is coupled to one end of the switch S21 and one end of the switch S22. The other of the two electrical terminals of the capacitor C12 is coupled to one end of the switch S31 and one end of the switch S32.

One of the two electrical terminals of the capacitor C21 is coupled to one end of the switch S13 and one end of the switch S14. The other of the two electrical terminals of the capacitor C21 is coupled to one end of the switch S23 and one end of the switch S24.

One of the two electrical terminals of the capacitor C22 is coupled to one end of the switch S23 and one end of the switch S24. The other of the two electrical terminals of the capacitor C22 is coupled to one end of the switch S33 and one end of the switch S34.

The capacitors C11 and C12 and the capacitors C21 and C22 can be charged or discharged in a complementary manner while a first phase and a second phase are repeatedly switched.

Specifically, in the first phase, the switches S12, S13, S22, S23, S32, and S33 are closed, and the switches S11, S14, S21, S24, S31, and S34 are opened. As a result, one of the two electrical terminals of the capacitor C11 is coupled to the node N3; the other of the two electrical terminals of the capacitor C11 and one of the two electrical terminals of the capacitor C21 are coupled to the node N2; and the other of the two electrical terminals of the capacitor C21 is coupled to the node N1. As a result, one of the two electrical terminals of the capacitor C12 is coupled to the node N2; the other of the two electrical terminals of the capacitor C12 and one of the two electrical terminals of the capacitor C22 are coupled to the node N1; and the other of the two electrical terminals of the capacitor C22 is coupled to a node N0 (ground).

By contrast, in the second phase, the switches S12, S13, S22, S23, S32, and S33 are opened, and the switches S11, S14, S21, S24, S31, and S34 are closed. As a result, one of the two electrical terminals of the capacitor C21 is coupled to the node N3; the other of the two electrical terminals of the capacitor C21 and one of the two electrical terminals of the capacitor C11 are coupled to the node N2; and the other of the two electrical terminals of the capacitor C11 is coupled to the node N1. As a result, one of the two electrical terminals of the capacitor C22 is coupled to the node N2; the other of the two electrical terminals of the capacitor C22 and one of the two electrical terminals of the capacitor C12 are coupled to the node N1; and the other of the two electrical terminals of the capacitor C12 is coupled to the node N0 (ground).

By repeatedly switching between the first phase and the second phase as described above, for example, when one of the capacitors C11 and C21 is charged through the node N3, the other of the capacitors C11 and C21 is discharged to the capacitor C20. In other words, the capacitors C11 and C21 can be charged or discharged in a complementary manner. Similarly, the capacitors C12 and C22 can be charged or discharged in a complementary manner.

According to the exemplary aspects, the capacitors C10 to C30 are smoothing capacitors. The capacitors C10 to C30 can be used to maintain and smooth the output voltages (i.e., second voltage V2, first voltage V1, and peak voltage Vpeak) at the nodes N1 to N3.

The capacitor C10 is coupled between the node N1 and ground. Specifically, one of the two electrical terminals of the capacitor C10 is coupled to the node N1. The other of the two electrical terminals of the capacitor C10 is coupled to the node N0 (i.e., ground).

The capacitor C20 is coupled between the nodes N2 and N1. Specifically, one of the two electrical terminals of the capacitor C20 is coupled to the node N2. The other of the two electrical terminals of the capacitor C20 is coupled to the node N1.

The capacitor C30 is coupled between the nodes N3 and N2. Specifically, one of the two electrical terminals of the capacitor C30 is coupled to the node N3. The other of the two electrical terminals of the capacitor C30 is coupled to the node N2.

The switch S11 is coupled between the capacitor C11 and the node N2. Specifically, one end of the switch S11 is coupled to one of the two electrical terminals of the capacitor C11. The other end of the switch S11 is coupled to the node N2.

The switch S12 is coupled between the capacitor C11 and the node N3. Specifically, one end of the switch S12 is coupled to one of the two electrical terminals of the capacitor C11. The other end of the switch S12 is coupled to the node N3.

The switch S21 is coupled between the capacitor C11 and the node N1. The switch S21 is coupled between the capacitor C12 and the node N1. Specifically, one end of the switch S21 is coupled to the other of the two electrical terminals of the capacitor C11 and one of the two electrical terminals of the capacitor C12. The other end of the switch S21 is coupled to the node N1.

The switch S22 is coupled between the capacitor C11 and the node N2. The switch S22 is coupled between the capacitor C12 and the node N2. Specifically, one end of the switch S22 is coupled to the other of the two electrical terminals of the capacitor C11 and one of the two electrical terminals of the capacitor C12. The other end of the switch S22 is coupled to the node N2.

The switch S31 is coupled between the capacitor C12 and the node N0 (i.e., ground). Specifically, one end of the switch S31 is coupled to the other of the two electrical terminals of the capacitor C12. The other end of the switch S31 is coupled to the node N0 (i.e., ground).

The switch S32 is coupled between the capacitor C12 and the node N1. Specifically, one end of the switch S32 is coupled to the other of the two electrical terminals of the capacitor C12. The other end of the switch S32 is coupled to the node N1.

The switch S13 is coupled between the capacitor C21 and the node N2. Specifically, one end of the switch S13 is coupled to one of the two electrical terminals of the capacitor C21. The other end of the switch S13 is coupled to the node N2. In other words, the other end of the switch S13 is coupled to the other end of the switch S11 and the other end of the switch S22.

The switch S14 is coupled between the capacitor C21 and the node N3. Specifically, one end of the switch S14 is coupled to one of the two electrical terminals of the capacitor C21. The other end of the switch S14 is coupled to the node N3. In other words, the other end of the switch S14 is coupled to the other end of the switch S12.

The switch S23 is coupled between the capacitor C21 and the node N1. The switch S23 is coupled between the capacitor C22 and the node N1. Specifically, one end of the switch S23 is coupled to the other of the two electrical terminals of the capacitor C21 and one of the two electrical terminals of the capacitor C22. The other end of the switch S23 is coupled to the node N1. In other words, the other end of the switch S23 is coupled to the other end of the switch S21 and the other end of the switch S32.

The switch S24 is coupled between the capacitor C21 and the node N2. The switch S24 is coupled between the capacitor C22 and the node N2. Specifically, one end of the switch S24 is coupled to the other of the two electrical terminals of the capacitor C21 and one of the two electrical terminals of the capacitor C22. The other end of the switch S24 is coupled to the node N2. In other words, the other end of the switch S24 is coupled to the other end of the switch S11, the other end of the switch S22, and the other end of the switch S13.

The switch S33 is coupled between the capacitor C22 and the node N0 (i.e., ground). Specifically, one end of the switch S33 is coupled to the other of the two electrical terminals of the capacitor C22. The other end of the switch S33 is coupled to the node N0 (i.e., ground). In other words, the other end of the switch S33 is coupled to the other end of the switch S31.

The switch S34 is coupled between the capacitor C22 and the node N1. Specifically, one end of the switch S34 is coupled to the other of the two electrical terminals of the capacitor C22. The other end of the switch S34 is coupled to the node N1. In other words, the other end of the switch S34 is coupled to the other end of the switch S21, the other end of the switch S32, and the other end of the switch S23.

According to the exemplary aspect and in operation, A first set of switches including the switches S12, S13, S22, S23, S32, and S33, and a second set of switches including the switches S11, S14, S21, S24, S31, and S34, can be controlled to open or close in a complementary manner via a control signal from the digital control circuit 60. Specifically, in the first phase, the switches of the first set are closed, and the switches of the second set are opened. Conversely, in the second phase, the switches of the first set are opened, and the switches of the second set are closed.

For example, in one of the first phase and the second phase, charging from the capacitors C11 and C12 to the capacitors C10 to C30 can be performed; and in the other of the first phase and the second phase, charging from the capacitors C21 and C22 to the capacitors C10 to C30 can be performed. In other words, the capacitors C10 to C30 can be constantly charged from the capacitors C11 and C12 or the capacitors C21 and C22. As a result, when current rapidly flows from the nodes N1 to N3 to the A-ET circuit 20 or the output switching circuit 30, supplemental charge successively moves to the nodes N1 to N3. As such, the potential variations at the nodes N1 to N3 can be suppressed.

By operating in this manner, the voltage generating circuit 10A is able to maintain approximately equal voltages across both ends of each of the capacitors C10 to C30. Specifically, Vpeak, V1, and V2 can be maintained at the three nodes N3 to N1 in a manner that satisfies (Vpeak−V1):(V1−V2):(V2−VG)=1:1:1.

It is noted that the ratio of (Vpeak−V1):(V1−V2):(V2−VG) is not limited to 1:1:1, and can be designed to fit any ratio according to various exemplary aspects.

### 2.3 Effects

As described above, in the tracker circuit 1A according to the present embodiment, the voltage generating circuit 10A includes a switched capacitor circuit configured to receive an input voltage, generate the peak voltage Vpeak, and the first voltage V1 and the second voltage V2, output the peak voltage Vpeak to the output switching circuit 30, and output the first voltage V1 and the second voltage V2 to the A-ET circuit 20.

With this configuration, three kinds of voltages, specifically the peak voltage Vpeak, the first voltage V1, and the second voltage V2, can be generated by a single switched capacitor circuit. As a result, the circuit configuration is simplified. When the tracker circuit 1A is modularized, this configuration helps reduce the size of the module.

The number of discrete voltages that can be output by the voltage generating circuit 10A is not limited to three. The number of discrete voltages output by the voltage generating circuit 10A can be four or more. Three voltages selected from the four or more discrete voltages can be used as the peak voltage Vpeak, the first voltage V1, and the second voltage V2. With this configuration, when the discrete voltages output by the voltage generating circuit 10A are set at regular intervals, the peak voltage Vpeak, the first voltage V1, and the second voltage V2 can be set at different intervals. As a result, a suitable voltage can be supplied to the power amplifier 2 to match the characteristics of radio-frequency signals or envelope signals. As such, this configuration helps enhance the power-added efficiency.

The voltage generating circuit 10A is not a switched capacitor circuit in some exemplary aspects. For example, the voltage generating circuit 10A is a multilevel converter that includes a power inductor and is configured to generate and output multiple kinds of voltages that differ from each other.

### 2.4 Module Configuration

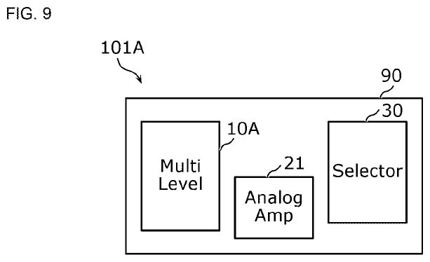

Next, a configuration of a module (tracker module) including the tracker circuit 1A according to the present embodiment will be described with reference to FIG. 9. The following primarily describes features that differ from the module configuration illustrated in FIG. 7, and descriptions of common features will not be repeated or will be simplified.

FIG. 9 is a plan view of an exemplary layout of circuit elements of the tracker circuit 1A according to the present embodiment. FIG. 9 illustrates an exemplary layout, and the circuit elements included in the tracker circuit 1A can be arranged in various layout configurations. Hence, the layout description provided below is provide as an exemplary aspect and should not be interpreted as limiting.

As illustrated in FIG. 9, a tracker module 101A includes circuit elements included in the circuit configuration of the tracker circuit 1A illustrated in FIG. 8, and a module substrate 90. Although not illustrated in the drawing, in some exemplary aspects, the tracker module 101A includes a resin member, an external connection terminal, and a shielding member.

In the present embodiment, the circuit elements are disposed on one of the major surfaces of the module substrate 90. In some exemplary aspects, the tracker module 101A is a single-sided mounting module with all circuit elements disposed on one side of the substrate. In some exemplary aspects, the tracker module 101A is a double-sided mounting module with circuit elements disposed on both sides of the substrate. In an example, the voltage generating circuit 10A, the amplifier 21, and the output switching circuit 30 are disposed on a major surface of the module substrate 90.

In the present embodiment, the voltage generating circuit 10A is formed by an integrated circuit and is disposed on a major surface of the module substrate 90. The integrated circuit is a semiconductor IC that is made, for example, using CMOS. In some exemplary aspects, the semiconductor IC is manufactured using an Si substrate or SOI substrate. For example, the integrated circuits are made of at least one of GaAs, SiGe, and GaN. The semiconductor material for the IC is not limited to the materials mentioned above.

As described above, the first voltage V1 and the second voltage V2 generated by the voltage generating circuit 10A can be supplied to the amplifier 21, and the peak voltage Vpeak can be supplied to the output switching circuit 30. For this reason, as illustrated in FIG. 9, the amplifier 21 is positioned between the voltage generating circuit 10A and the output switching circuit 30 in a plan view. This configuration shortens the interconnection paths for voltage supply, thereby reducing parasitic capacitance and parasitic inductance.

In FIG. 8, the capacitor 22 included in the A-ET circuit 20, the inductor 41 and the capacitor 42 included in the filter circuit 40, and the first controller 61 and the second controller 62 included in the digital control circuit 60 are not illustrated. For example, the capacitors 22 and 42 and the inductor 41 are formed as surface mount devices (SMDs) such as chip capacitors and chip inductors, or integrated passive devices (IPDs) and mounted at the module substrate 90. In some exemplary aspects, at least one of the capacitors 22 and 42 and the inductor 41 are formed by, for example, a wiring pattern provided at the module substrate 90. The first controller 61 and the second controller 62 are formed by integrated circuits and mounted at the module substrate 90. In some exemplary aspects, the first controller 61 and the second controller 62 are provided in the same integrated circuit as any of the voltage generating circuit 10A, the amplifiers 21, and the output switching circuit 30.

### Additional Exemplary Embodiments

The tracker circuit, the communication device, and the voltage supply method according to exemplary aspects of the present disclosure have been described above based on the exemplary embodiments. However, the tracker circuit, the communication device, and the voltage supply method according to the present disclosure are not limited to the exemplary embodiments. The present disclosure also embraces other embodiments implemented by any combination of the constituent elements of the exemplary embodiments, other modifications obtained by making various modifications that occur to those skilled in the art without departing from the scope of the disclosure, and various hardware devices including the tracker circuits described above.

For example, in the different circuit configurations according to the exemplary embodiments described above, other circuit elements and/or interconnections are also inserted in the paths connecting the circuit elements and the signal paths that are illustrated in the drawings. For example, an inductor and/or capacitor is inserted between the tracker circuit and the power amplifier.

In the first exemplary embodiment, an example in which an identical input voltage can be input to the DC-DC converters 11 to 13 is described. However, this is not to be interpreted as limiting. In some exemplary aspects, different input voltages are input to at least two of the DC-DC converters 11 to 13.

The present disclosure may also be embodied in other forms that can be achieved by applying various modifications to the above-described exemplary embodiments that occur to those skilled in the art, or by combining the constituent elements and functions in the exemplary embodiments in any manner without departing from the spirit and scope of the present disclosure.

The following describes the features of the tracker circuit, the communication device, and the voltage supply method explained using the exemplary embodiments.

According to some exemplary aspects, a tracker circuit includes an analog envelope tracking (A-ET) circuit configured to generate a continuously varying voltage, a voltage generating circuit configured to generate a peak voltage that is higher than a maximum voltage value of the continuously varying voltage, and an output switching circuit configured to receive the continuously varying voltage and the peak voltage. The output switching circuit is configured to, when an envelope value is smaller than a threshold, output the continuously varying voltage to a power amplifier, and when an envelope value is greater than the threshold, output the peak voltage to the power amplifier.

According to an exemplary aspect, the A-ET circuit includes an amplifier configured to receive a first voltage and amplify an envelope signal, and the A-ET circuit is configured to generate the continuously varying voltage by combining the envelope signal amplified by the amplifier with a second voltage.

According to an exemplary aspect, the A-ET circuit includes a first input terminal configured to receive a first voltage, a second input terminal configured to receive a second voltage, a third input terminal configured to receive an envelope signal, a first output terminal configured to output the continuously varying voltage, and an amplifier including a power supply terminal coupled to the first input terminal, a fourth input terminal coupled to the third input terminal, and a second output terminal coupled to the first output terminal, and the second input terminal is coupled to the first output terminal.

According to an exemplary aspect, the A-ET circuit includes a capacitor provided in series in a path connecting the first output terminal to the second output terminal.

According to an exemplary aspect, the voltage generating circuit includes a first converter configured to convert an input voltage into the peak voltage and output the peak voltage to the output switching circuit, a second converter configured to convert an input voltage into the first voltage and output the first voltage to the A-ET circuit, and a third converter configured to convert an input voltage into the second voltage and output the second voltage to the A-ET circuit.

According to an exemplary aspect, the voltage generating circuit includes a switched capacitor circuit configured to receive an input voltage and generate the peak voltage, the first voltage, and the second voltage, output the peak voltage to the output switching circuit, and output the first voltage and the second voltage to the A-ET circuit.

According to an exemplary aspect, the first voltage is equal to a magnitude obtained by subtracting the second voltage from a third voltage that is higher than the second voltage, and the peak voltage is higher than the third voltage.

According to an exemplary aspect, the tracker circuit includes a control terminal configured to receive a parallel data signal for controlling the output switching circuit.

According to an exemplary aspect, the tracker circuit includes a filter circuit coupled between the output switching circuit and the power amplifier.

According to some exemplary aspects, a tracker circuit includes an A-ET circuit configured to generate a continuously varying voltage, a voltage generating circuit configured to generate a peak voltage that is higher than a maximum voltage value of the continuously varying voltage, and an output switching circuit configured to receive the continuously varying voltage and the peak voltage. The output switching circuit is configured to, when an average power within a single frame is smaller than a threshold, output the continuously varying voltage to a power amplifier, and when an average power within a single frame is greater than the threshold, output the peak voltage to the power amplifier.

According to some exemplary aspects, a communication device includes the tracker circuit, a signal processing circuit configured to process a radio-frequency signal, and a radio-frequency circuit including the power amplifier. The radio-frequency circuit is configured to transfer the radio-frequency signal between the signal processing circuit and an antenna.

According to some exemplary aspects, a voltage supply method includes generating a continuously varying voltage, generating a peak voltage that is higher than a maximum voltage value of the continuously varying voltage, when an envelope value is smaller than a threshold, outputting the continuously varying voltage to a power amplifier, and when an envelope value is greater than the threshold, outputting the peak voltage to the power amplifier.

According to some exemplary aspects, a voltage supply method includes generating a continuously varying voltage, generating a peak voltage that is higher than a maximum voltage value of the continuously varying voltage, and when an average power within a single frame is smaller than a threshold, outputting the continuously varying voltage to a power amplifier, and when an average power within a single frame is greater than the threshold, outputting the peak voltage to the power amplifier.

In general, according to the exemplary aspects, the present disclosure can be used as a tracker circuit that supplies voltage to a power amplifier in a wide variety of communication devices such as mobile phones.

What is claimed:

1. A tracker circuit, comprising:
an analog envelope tracking (A-ET) circuit configured to generate a continuously varying voltage that is associated with an envelope of a signal to be amplified by a power amplifier;
a voltage generating circuit configured to generate a peak voltage that is higher than a maximum voltage value of the continuously varying voltage; and
an output switching circuit configured to receive the continuously varying voltage and the peak voltage,
wherein the output switching circuit is configured to, when an envelope value of the signal to be amplified by the power amplifier is smaller than a threshold, output the continuously varying voltage to the power amplifier as a first supply voltage of the power amplifier, and when the envelope value is greater than the threshold, output the peak voltage to the power amplifier as the first supply voltage of the power amplifier.

2. The tracker circuit according to claim 1, wherein:
the A-ET circuit includes an amplifier that is configured to receive a first voltage as a second supply voltage of the amplifier and to amplify an envelope signal corresponding to the envelope of the signal to be amplified by the power amplifier to generate an amplified envelope signal according to the second supply voltage, and
the A-ET circuit is configured to generate the continuously varying voltage by combining the amplified envelope signal with a second voltage.

3. The tracker circuit according to claim 2, wherein:
the A-ET circuit includes:
a first input terminal configured to receive the first voltage;
a second input terminal configured to receive the second voltage;
a third input terminal configured to receive the envelope signal;
a first output terminal configured to output the continuously varying voltage; and
the amplifier including a power supply terminal coupled to the first input terminal, a fourth input terminal coupled to the third input terminal, and a second output terminal coupled to the first output terminal; and
the second input terminal is coupled to the first output terminal.

4. The tracker circuit according to claim 3, wherein the A-ET circuit includes a capacitor that connects the first output terminal to the second output terminal.

5. The tracker circuit according to claim 2, wherein the voltage generating circuit includes:
a first converter configured to convert an input voltage into the peak voltage;
a second converter configured to convert the input voltage into the first voltage; and
a third converter configured to convert the input voltage into the second voltage.

6. The tracker circuit according to claim 2, wherein the voltage generating circuit includes a switched capacitor circuit configured to receive an input voltage and to generate the peak voltage, the first voltage, and the second voltage according to the input voltage.

7. The tracker circuit according to claim 2, wherein:
the first voltage is obtained by subtracting the second voltage from a third voltage that is higher than the second voltage, and
the peak voltage is higher than the third voltage.

8. The tracker circuit according to claim 1, wherein the tracker circuit includes a control terminal configured to receive a data signal for controlling the output switching circuit, the data signal being generated based on the signal to be amplified by the power amplifier.

9. The tracker circuit according to claim 1, further comprising a filter circuit coupled between the output switching circuit and the power amplifier and being configured to filter an output of the output switching circuit and to provide the filtered output as the first supply voltage of the power amplifier.

10. The tracker circuit according to claim 2, wherein the amplifier is configured to be de-activated when the envelope value is greater than the threshold.

11. A method of amplifying, comprising:
generating a continuously varying voltage that is associated with an envelope of a signal to be amplified by a power amplifier;
generating a peak voltage that is higher than a maximum voltage value of the continuously varying voltage;
providing the continuously varying voltage to the power amplifier as a first supply voltage of the power amplifier when an envelope value of the signal to be amplified by the power amplifier is smaller than a threshold; and
providing the peak voltage to the power amplifier as the first supply voltage of the power amplifier when the envelope value is greater than the threshold.

12. The method according to claim 11, wherein the generating of the continuously varying voltage comprises:
amplifying, based on a second supply voltage of a first voltage, an envelope signal corresponding to the envelope of the signal to be amplified by the power amplifier to generate an amplified envelope signal; and
generating the continuously varying voltage by combining the amplified envelope signal with a second voltage.

13. The method according to claim 12, wherein the combining comprises combining the amplified envelope signal with the second voltage by a capacitor.

14. The method according to claim 12, wherein the generating of the peak voltage comprises:
subtracting the second voltage from a third voltage that is higher than the second voltage to generate the first voltage; and
generating the peak voltage that is higher than the third voltage.

15. The method according to claim 11, further comprising:
generating a data signal based on the signal to be amplified by the power amplifier; and
controlling an output switching circuit to select one of the peak voltage and the continuously varying voltage based on the data signal.

16. The method according to claim 15, further comprising:
filtering an output of the output switching circuit; and
providing the filtered output as the first supply voltage of the power amplifier.

17. The method according to claim 12, further comprising de-activating an amplifier for the amplifying of the envelop signal when the envelope value is greater than the threshold.

18. A communication device, comprising:
a signal processing circuit configured to process a radio-frequency signal;
a radio-frequency circuit including a power amplifier that is configured to amplify the radio-frequency signal; and
a tracker circuit that includes:
an analog envelope tracking (A-ET) circuit configured to generate a continuously varying voltage that is associated with an envelope of the radio-frequency signal to be amplified by the power amplifier;
a voltage generating circuit configured to generate a peak voltage that is higher than a maximum voltage value of the continuously varying voltage; and
an output switching circuit configured to receive the continuously varying voltage and the peak voltage,
wherein the output switching circuit is configured to, when an envelope value of the radio-frequency signal is smaller than a threshold, output the continuously varying voltage to the power amplifier as a first supply voltage of the power amplifier, and when the envelope value is greater than the threshold, output the peak voltage to the power amplifier as the first supply voltage of the power amplifier.

19. The communication device according to claim 18, wherein:
the A-ET circuit includes an amplifier that is configured to receive a first voltage as a second supply voltage of the amplifier and to amplify an envelope signal corresponding to the envelope of the radio-frequency signal to generate an amplified envelope signal according to the second supply voltage; and
the A-ET circuit is configured to generate the continuously varying voltage by combining the amplified envelope signal with a second voltage.

20. The communication device according to claim 19, wherein the amplifier is configured to be de-activated when the envelope value is greater than the threshold.
